(19) United States
(12) Patent Application Publication
(10) Pub. No.: US 2006/0022197 A1
(43) Pub. Date: Feb. 2, 2006

(54) Technique for evaluating local electrical characteristics in semiconductor devices

(76) Inventors: Frank Wirbeleit, Freiberg (DE); Gert Burbach, Dresden (DE); Karsten Wieczorek, Dresden (DE); Manfred Horstmann, Duerrroehrsdorf-Dittersbach (DE)

Correspondence Address: WILLIAMS, MORGAN & AMERSON, P.C., 10333 RICHMOND, SUITE 1100, HOUSTON, TX, 77042, US

(21) Appl. No.: 11/099,755

(22) Filed: Apr. 6, 2005

(30) Foreign Application Priority Data
Jul. 30, 2004 (DE) 10 2004 036 971.2

(51) Int. Cl. H01L 23/58

(52) U.S. Cl. 257/48

(57) ABSTRACT

By providing a test structure including a plurality of test pads, the anisotropic behavior of stress and strain influenced electrical characteristics, such as the electron mobility, may be determined in a highly efficient manner. Moreover, the test pads may enable the detection of stress and strain induced modifications with a spatial resolution in the order of magnitude of individual circuit elements.

### BACKGROUND OF THE INVENTION

1. Field of the Invention

Generally, the present invention relates to the formation of integrated circuits, and, more particularly, to the formation of semiconductor regions of different characteristics, such as different charge carrier mobilities in channel regions of a field effect transistor, on a single substrate and the evaluation of the characteristics.

2. Description of the Related Art

The fabrication of integrated circuits requires the formation of a large number of circuit elements on a given chip area according to a specified circuit layout. Generally, a plurality of process technologies are currently practiced, wherein, for complex circuitry, such as microprocessors, storage chips and the like, MOS technology is currently the most promising approach due to the superior characteristics in view of operating speed and/or power consumption and/or cost efficiency. During the fabrication of complex integrated circuits using MOS technology, millions of transistors, i.e., N-channel transistors and/or P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an appropriately doped channel region disposed between the drain region and the source region.

The conductivity of the channel region, i.e., the drive current capability of the conductive channel, is controlled by a gate electrode formed above the channel region and separated therefrom by a thin insulating layer. The conductivity of the channel region upon formation of a conductive channel due to the application of an appropriate control voltage to the gate electrode depends, among others, on the dopant concentration, the mobility of the charge carriers, and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially influences the performance of MOS transistors. Thus, the reduction of the channel length, and associated therewith the reduction of the channel resistivity, renders the channel length a dominant design criterion for accomplishing an increase in the operating speed of the integrated circuits.

The continuing shrinkage of the transistor dimensions, however, entails a plurality of issues associated therewith that have to be addressed so as to not unduly offset the advantages obtained by steadily decreasing the channel length of MOS transistors. One major problem in this respect is the development of enhanced photolithography and etch strategies to reliably and reproducibly create circuit elements of critical dimensions, such as the gate electrode of the transistors, for a new device generation. Moreover, highly sophisticated dopant profiles, in the vertical direction as well as in the lateral direction, are required in the drain and source regions to provide low sheet and contact resistivity in combination with a desired channel controllability. In addition, the vertical location of the PN junctions with respect to the gate insulation layer also represents a critical design criterion in view of leakage current control. Hence, reducing the channel length also requires reducing the depth of the drain and source regions with respect to the interface formed by the gate insulation layer and the channel region, thereby requiring sophisticated implantation techniques. According to other approaches, epitaxially grown regions are formed with a specified offset to the gate electrode, which are referred to as raised drain and source regions, to provide increased conductivity of the raised drain and source regions, while at the same time maintaining a shallow PN junction with respect to the gate insulation layer.

Since the continuous size reduction of the critical dimensions, i.e., the gate length of the transistors, necessitates the adaptation and possibly the new development of highly complex process techniques concerning the above-identified process steps, it has been proposed to also enhance device performance of the transistor elements by increasing the charge carrier mobility in the channel region for a given channel length, thereby offering the potential for achieving a performance improvement that is comparable with the advance to a further scaled technology node while avoiding many of the above process adaptations associated with device scaling.

In principle, at least two mechanisms may be used, in combination or separately, to increase the mobility of the charge carriers in the channel region. First, the dopant concentration within the channel region may be reduced, thereby reducing scattering events for the charge carriers and thus increasing the conductivity. However, reducing the dopant concentration in the channel region significantly affects the threshold voltage of the transistor device, thereby presently making a reduction of the dopant concentration a less attractive approach unless other mechanisms are developed to adjust a desired threshold voltage. Second, the lattice structure, typically a (100) surface orientation, in the channel region may be modified, for instance by creating tensile or compressive stress to produce a corresponding strain in the channel region, which results in a modified mobility for electrons and holes, respectively. For example, creating tensile strain in the channel region increases the mobility of electrons, wherein, depending on the magnitude and direction of the tensile strain, an increase in mobility of 120% or more may be obtained, which, in turn, may directly translate into a corresponding increase in the conductivity. On the other hand, compressive strain in the channel region may increase the mobility of holes, thereby providing the potential for enhancing the performance of P-type transistors.

The introduction of stress or strain engineering into integrated circuit fabrication is an extremely promising approach for further device generations, since, for example, strained silicon may be considered as a “new” type of semiconductor material, which may enable the fabrication of fast powerful semiconductor devices without requiring expensive semiconductor materials and manufacturing techniques. Consequently, it has been proposed to introduce, for instance, global strain by means of a silicon/germanium layer or a silicon/carbon layer formed on a silicon substrate to obtain the desired strain in the channel region.

In other approaches, locally created stress produced by, for instance, overlaying layers, spacer elements, trench isolation structures and the like is modified in an attempt to create a desired strain within the channel region. However, the process of creating the strain in the channel region by applying a specified external stress may strongly depend on the device architecture, process techniques, materials used and the like, since the translation of the locally created stress into strain in the channel region is affected by, for instance, how strongly the channel region is bonded to the buried insulating layer in SOI (silicon-on-insulator) devices or the remaining bulk silicon in bulk devices, how much stress and with which direction can be produced in a specified area, and the like.

Recently, it has been proposed to provide so-called hybrid substrates that include silicon regions of two different orientations, that is, a (100) surface orientation and a (110) surface orientation, due to the well-known fact that the hole mobility in (110) silicon is approximately 2.5 times the mobility in (100) silicon. Thus, by providing a (110) channel region for P-channel transistors in CMOS circuits while maintaining the (100) orientation providing a superior electron mobility in the channel regions of the N-channel transistors, the performance of circuits containing both types of transistors may significantly be enhanced for any given transistor architecture. The introduction of two types of crystal orientation in a single substrate may require additional complex process steps.

As a consequence, in advanced integrated circuits fabricated by using one or more of the above-identified techniques, the electrical characteristics may significantly depend on the finally achieved channel conductivity, and, hence, one or more of the factors determining the conductivity have to be monitored. In particular, strain engineering is considered a promising candidate for future device generations. In view of this situation, there exists a need for a technique that enables efficient evaluation of local device characteristics, in particular the stress and strain conditions and/or other parameters affecting the charge carrier mobility, in different substrate areas.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that allows evaluation of electrical characteristics, such as conductivity, electron mobility and the like, in a highly localized and, if desired, in a direction-dependent manner, thereby providing the potential for estimating particularly stress and strain induced effects on the performance of transistor structures.

According to one illustrative embodiment of the present invention, a semiconductor device comprises a semiconductor region formed in a device layer located above a substrate. A plurality of test pads are provided and are electrically coupled to the semiconductor region for measuring at least one directional characteristic of the semiconductor region. A first two of the test pads are arranged along a first direction and a second two of the test pads are arranged along a second direction that is different from the first direction.

According to a further illustrative embodiment of the present invention, a semiconductor device comprises a semiconductor region formed above a substrate and a test structure that is formed in the semiconductor region. The test structure is configured to determine a conductivity of the semiconductor region in at least two different directions.

According to still another illustrative embodiment of the present invention, a method comprises determining, with respect to at least two linearly independent directions, an electrical property of a semiconductor region that is located in a device layer of a semiconductor device. The method further comprises evaluating at least one specific characteristic influencing a charge carrier mobility in the semiconductor region on the basis of the determined electrical property.

### BRIEF DESCRIPTION OF THE DRAWINGS

The invention may be understood by reference to the following description taken in conjunction with the accompanying drawings, in which like reference numerals identify like elements, and in which:

FIGS. 1a-1b schematically show in plan view and cross-sectional view, respectively, a test structure for determining electrical properties along two linearly independent directions in a specified plane of a semiconductor region of interest;

FIGS. 1c-1d schematically show in plan view a test structure according to further illustrative embodiments;

FIG. 1e schematically illustrates a cross-sectional view of a test structure including a gate structure in accordance with further illustrative embodiments of the present invention;

FIG. 2 schematically depicts in plan view a test structure including two differently oriented transistor structures in accordance with one illustrative embodiment;

FIG. 3 illustrates in plan view an array of test pads requiring a reduced number of contact pads according to illustrative embodiments; and

FIG. 4 shows in cross-sectional view a test structure including a reference test structure for determining substantially isotropic electrical characteristics in accordance with a further illustrative embodiment.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is based on the concept of defining electrical characteristics in a localized manner by providing appropriate test structures that may be readily implemented in currently established process flows without consuming an undue amount of real estate, i.e., space, on the semiconductor substrate. In future device generations, stress and strain engineering may become an important design criterion and it may significantly influence the overall performance of the devices, possibly in combination with the introduction of heterostructures in the channel regions and the employment of different crystallographic orientations within the same substrate. Many of these aspects may be introduced during the manufacturing sequence and may also be applied and modified to vary even within a single substrate so that highly effective means are required to monitor and control the effects of various process specific modifications, especially stress and strain inducing processes. Stress and strain engineering as well as the provision of different crystallographic orientations may be performed in a very localized manner, as even different types of transistors in a complementary transistor pair may receive a different treatment. Thus, the test structures may advantageously be designed to provide the desired information with a “spatial resolution” that allows the estimation of electrical characteristics on a scale, which at least conforms with the size of the transistor element or other circuit elements, the performance of which significantly depends on the local electrical characteristics.

It is to be noted that a semiconductor device typically includes a plurality of circuit elements formed on the basis of a semiconductive material, wherein these circuit elements are usually formed on a specified level in a substantially planar configuration. In this application, a corresponding level including circuit elements, such as transistors, capacitors and the like, is referred to as a device layer. On the other hand, the individual circuit elements formed in the device layer of the semiconductor device have to be electrically connected in conformity with a specified circuit layout to build up specified functional blocks that may include one or more of the individual circuit elements in the device layer. In complex integrated circuits, the electrical connection between the individual circuit elements may not be established within the device layer and may usually require the formation of one or more additional “wiring” layers including highly conductive lines and vias, wherein the lines provide an inter-layer connection, while the vias provide electrical contact between neighboring layers comprising conductive lines. A corresponding wiring layer including metal lines and vias may also be referred to as a metallization layer. Although the total performance of a semiconductor device is also significantly affected by the characteristics of the metallization layers, as for example the introducing of mechanical stress may influence the conductivity and the reliability of metal lines and metal vias, the present invention is concerned with techniques for controlling and monitoring parameters influencing electrical characteristics within the device layer, such as the introduction of locally exerted stress.

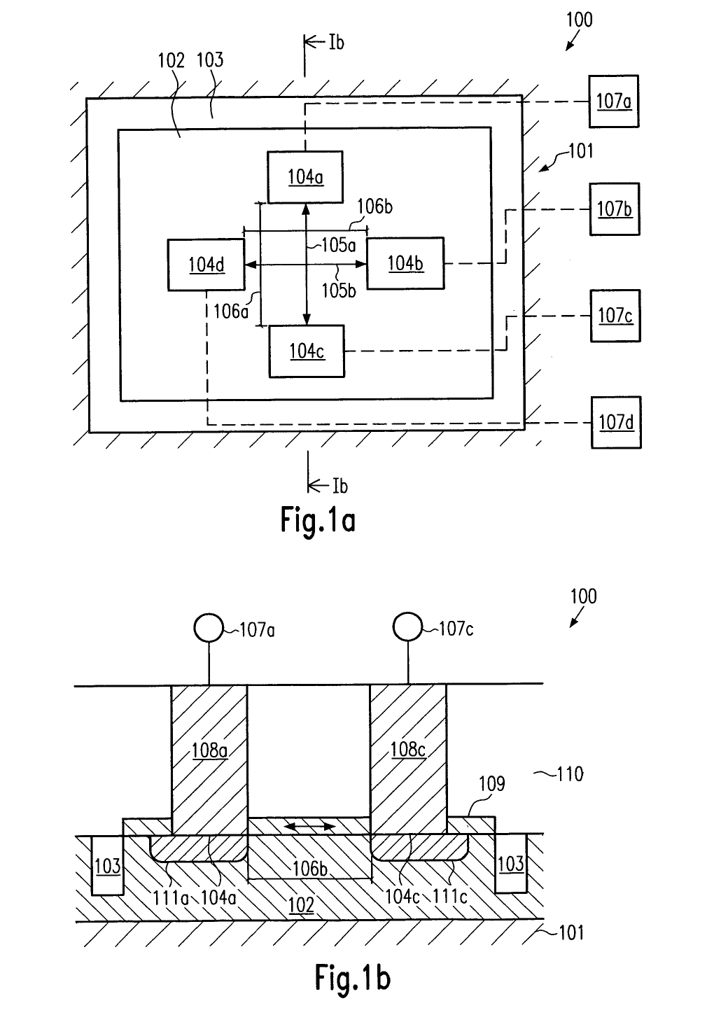

With reference to the accompanying drawings, further illustrative embodiments of the present invention will now be described in more detail. FIG. 1a schematically shows in plan view a semiconductor device 100 comprising a substrate 101, which may represent any appropriate substrate, such as bulk semiconductor substrates, insulating substrates having formed thereon a crystalline semiconductor layer, wherein the semiconductor layer may include one or more semiconductor materials. In particular embodiments, the substrate 101 may represent a bulk silicon substrate or an SOI (silicon-on-insulator) substrate, as the vast majority of complex integrated circuits, such as microprocessors, storage devices, ASICs and the like, are fabricated on the basis of silicon. It should be emphasized, however, that the embodiments shown and described herein may be readily employed in combination with any appropriate substrates, such as gallium arsenide, silicon/germanium substrates, insulating substrates having formed thereon one or more strained semiconductor layers, and the like.

Formed above the substrate 101 is a semiconductor region 102, which in some embodiments may be enclosed by an isolation structure 103, while in other embodiments a border of the semiconductor region 102 may not precisely be defined but may be determined by neighboring regions that may include circuit elements or other test structures and the like. The isolation structure 103, if provided, may represent any type of isolation structure, such as a shallow trench isolation (STI), as is frequently used in advanced semiconductor devices.

The semiconductor device 100 further comprises a plurality of test pads 104a, 104b, 104c, 104d which are in contact with the semiconductor region 102. The test pads 104a, 104b, 104c, 104d may represent exposed surface portions of the semiconductor region 102, which may be contacted by an external electrical probe, or the test pads 104a, 104b, 104c, 104d may represent an interface between a surface portion of the semiconductor region 102 and a conductive material, for instance provided in the form of a plug formed within a dielectric layer that is formed over the semiconductor region 102. For example, the test pads 104a, 104b, 104c, 104d may represent the interface between the semiconductor region 102 and a metal plug comprised of tungsten or tungsten silicide, wherein a surface portion of the semiconductor region 102 below the test pads 104a, 104b, 104c, 104d may be doped in a concentration to establish a substantially ohmic behavior of the test pads 104a, 104b, 104c, 104d.

The plurality of test pads 104a, 104b, 104c, 104d are arranged in such a manner that at least two of the test pads, for instance the pads 104a and 104c, define a first direction of interest 105a, while two of the test pads, such as the pads 104b and 104d, define a second direction of interest 105b. Moreover, the test pads 104a, 104b, 104c, 104d may be disposed such that a desired first distance 106a along the first direction 105a and a desired second distance 106b along the second direction 105b are obtained.

As previously explained, the first and second distances 106a, 106b may be selected in conformity with design rules and may, in some embodiments, be selected to be within the order of magnitude of a circuit element, such as a transistor of the technology node under consideration. For instance, the first and second distances 106a, 106b may range from several tenths of nanometers to several hundred nanometers for advanced devices. In other embodiments, when the evaluation of electrical parameters on a larger scale is required, the first and second distances may range from several hundred nanometers to a few micrometers. In particular embodiments, the first and second direction 105a, 105b are substantially perpendicular to each other. It should be appreciated that the arrangement of the test pads 104a, 104b 104c, 104d comprising at least four individual pads may be considered as representing other distances and directions of interest, wherein specific distances and directions may be selected by the operational mode in which the test pads 104a, 104b, 104c, 104d are operated. For example, the pads 104a and 104b may define a distance therebetween and may also define a third direction of interest that substantially forms an angle of approximately 45 degrees with the first and second directions 105a, 105b when the first and second distances 106a and 106b are substantially identical. For convenience, any further distances and directions are not shown in FIG. 1a and will be described later on so as to not unduly obscure the basic concept of the present invention.

The semiconductor device 100 further comprises a plurality of contact pads 107a, 107b, 107c, 107d, each of which is electrically connected to at least one of the test pads 104a, 104b, 104c, 104d. In the embodiment shown in FIG. 1a, each contact pad 107a, 107b, 107c, 107d is electrically connected with one of the test pads 104a, 104b, 104c, 104d. The contact pads 107a, 107b, 107c, 107d represent any contact region that is configured to enable contact to an external electrical probe such as an electrode of a measurement device. Hence, in some embodiments, the contact pads 107a, 107b, 107c, 107d may represent a conductive material layer formed on the pads 104a, 104b, 104c, 104d, while, in other embodiments, the contact pads 107a, 107b, 107c, 107d are specifically designed areas of conductive material, for instance formed above one or more metallization layers, wherein the electrical connection is established by means of metal lines and vias of the one or more metallization layers.

In particular embodiments, the semiconductor region 102 may represent a strained semiconductor region or a region having internal stress, wherein the strain or stress may be created by specific measures, such as a stress layer, ion implantation, the provision of a different semiconductor material layer having a mismatch in lattice spacing to the surrounding semiconductor material, and the like, some of which were discussed in the background section of the present application.

FIG. 1b schematically shows a cross-sectional view of the semiconductor device 100 along the line indicated by 1b in FIG. 1a. A dielectric layer 110, for instance comprised of silicon dioxide and/or silicon nitride, is formed above the semiconductor region 102, wherein a stress-inducing layer 109, for instance comprised of silicon nitride having a specified internal stress, is located above the semiconductor region 102. It should be appreciated that the stress-inducing layer 109 is of illustrative nature only and is to represent any means for creating stress or strain in the semiconductor region 102, the influence of which on electrical characteristics of the region 102 is to be estimated or determined. As another example of a strain-inducing source, the isolation structure 103 may be formed with specified process conditions to exert a specified stress to the semiconductor region 102 and therefore may also be considered as a source of influencing the electrical characteristics of the region 102. In other embodiments, the semiconductor region 102 may be located in close proximity to a stress-inducing region (not shown) so that a certain amount of strain is created in the semiconductor region 102. In other embodiments, additionally or alternatively, the semiconductor region 102 may represent a region of a specified first crystallographic orientation, which has been formed on a substrate having a second different crystallographic orientation. For example, a plurality of silicon regions having a (110) surface orientation may be formed on a (100) substrate, and the influence on electrical characteristics for a specified manufacturing process may be assessed with respect to the difference in crystallographic orientation.

In the embodiment illustrated in FIG. 1b, the test pads 104d and 104b are formed by respective metal plugs 108d and 108b formed in the dielectric layer 110 and the stress-inducing layer 109. Depending on the type of material used in the plugs 108d and 108b, respective regions 111d and 111b located below the plugs may be doped to form a substantially ohmic contact with the test pads 104d and 104b. In some embodiments, when the plugs 108d and 108b are substantially comprised of aluminum, the dopant concentration typically prevailing within the semiconductor region 102 may be sufficient to provide an ohmic contact instead of a Schottky contact. Moreover, as previously noted, the test pads 104d, 104b may be directly contacted by an external probe, depending on the dimensions and the configuration of the semiconductor device 100. In this case, depending on the characteristics of the electrical probes, such as material composition, the highly doped regions 111d and 111b may be provided or not. Furthermore, in such a case, the test pads 104d, 104b may also represent the contact pads 107d and 107b. For the further description it is assumed that electrical contact to the test pads 104d, 104b is established by means of the plugs 108d, 108b and the contact pads 107d and 107b, which, in turn, may be represented by the surface portion of the plugs 108d, 108b, or any other appropriate conductive surface configured to enable access by an electrical probe. For example, specifically designed pad areas may be provided in one of the metallization layers or on the final passivation layer along with I/O leads.

The semiconductor device 100 as shown in FIGS. 1a-1b may be formed by well established processes, including advanced photolithography, anisotropic etch techniques and deposition methods for forming the isolation trenches within the substrate 101, wherein prior to or after the formation of the isolation structure 103 corresponding implantation sequences may be performed to establish a required dopant profile within the semiconductor region 102. In particular embodiments, any process sequences may follow that are typically used in forming circuit elements in semiconductor regions adjacent to the region 102, wherein, in some of the processes, the region 102 may be masked to obtain the required configuration of the test pads 104a, 104b, 104c, 104d in and/or above the region 102 of the semiconductor device 100. For instance, the formation of a gate electrode structure may be avoided, if desired, on the region 102, whereas the implantation mask used for selectively doping P-type regions and N-type regions may be modified to allow the formation of the regions 111d, 111b, if required. The further process sequence may be continued in accordance with device requirements to thereby form the stress-inducing layer 109, the dielectric layer 110, the plugs 108d, 108b, and the contact pads 107d and 107b.

Referring to FIGS. 1a-1b, the semiconductor device 100 is described when being operated to estimate electrical characteristics of the semiconductor region 102. As is well known, the conductivity of a semiconductor region, such as the region 102, is, among other things, directly proportional to the charge carrier mobility, which in turn is significantly influenced by the magnitude, type and direction of strain within a semiconductor region and also strongly depends on the crystallographic orientation of the semiconductor region 102. For example, for a (100) crystallographic surface orientation, the hole mobility may be significantly increased for compressive stress acting along the current flow direction, while compressive stress along a direction perpendicular to the current flow may only have a reduced effect of mobility enhancement. Similarly, the electron mobility may also be affected in different manners for compressive or tensile strain in a direction parallel and perpendicular to the direction of the current flow.

In order to evaluate electrical characteristics of the region 102 in a direction-dependent fashion, the contact pads 107a and 107c may be contacted by means of electrical probes connected to a measurement device that enables, for example, determining the electrical resistance between the contact pads 107a and 107c, and thus the resistivity of the region 102 between the test pads 104a and 104c. For determining the resistivity of the semiconductor region 102 by means of the pads 104a, 104c, a specified current may be driven through the region and the voltage required therefor may be recorded to evaluate the resistivity. In other examples, a specified voltage may be supplied to the pads 107a, 107c, and the resulting current flow may be determined. At any rate, a voltage is created between the pads 104a and 104c, and thus a voltage drop and an electrical field occurs within the semiconductor region 102, wherein the electric field is substantially oriented along the first direction 105a so that a corresponding current flow is also substantially directed along the first direction 105a. Hence, the electrical characteristic estimated on the basis of the current flow between the pads 104a and 104c enables a direction-dependent estimation of the electrical characteristic under consideration, such as the conductivity, and thus the charge carrier mobility. Similarly, the contact pads 107b and 107d may be connected to an external measurement device and a corresponding electrical characteristic may be estimated for the second direction 105b.

In embodiments in which the first and second distances 106a, 106b are substantially identical, the corresponding measurement values may be directly compared to detect any anisotropic, i.e., directional, behavior of the electrical characteristic under consideration. Otherwise, the measurement values may be normalized with respect to the respective distance. As previously noted, it may be advantageous to select the first and second distances 106a, 106b in conformity with typical device dimensions so that any strain-inducing measures, such as the provision of stress-inducing layers, the provision of heterostructures, and the like, may be examined and monitored in view of their direction-dependent effects on electrical parameters, such as electron mobility, wherein microscopic effects, such as a variation of the lattice spacing, may be detected by macroscopic parameters such as current and voltage. The measurement results may then be readily used in controlling a specified process flow for forming a semiconductor device under consideration in that a correlation is established between the finally obtained electrical performance of specific circuit elements, such as transistor elements, and the electrical measurement data obtained by the test structure of the device 100, whereby a correlation to specific parameters of the process flow, such as type of materials used, characteristics of any strain engineering techniques, and the like, may also be established. Corresponding correlations may be readily obtained on the basis of a plurality of test substrates including the semiconductor device 100, as shown in FIGS. 1a-1b, processed under varied conditions.

In other embodiments, influences of electrical fields or current flows within a semiconductor region on stress and strain dependent characteristics in that region may be examined. For example, a specified current flow may be established between two of the pads 104a, 104b, 104c, 104d, while two other of the pads may be used as measurement pads. For instance, for a specified current or voltage between the pads 104a and 104c, the conductivity between the pads 104b and 104d may be determined in a manner as previously described. In other cases, the voltage drop between the pads 104b and 104d may be determined and may be used to estimate a dependency on direction of one or more electrical characteristics. Thereafter, the pads 104d and 104b may be used as pads for driving current through the region 102 or applying a voltage while the pads 104a and 104c may be used as monitoring pads. In other embodiments, at least one of the pads 104a, 104b, 104c, 104d may be provided with an insulating layer thereon so that an electrical field of desired magnitude may be established without inducing an external current flow by applying specified voltage on the respective contact pads. For instance, it is assumed that the pads 104d and 104b have formed thereon thin insulating layers and a specified voltage is applied to the pads 107d and 107b to establish a specified electrical field along the second direction 105b, the magnitude of which is defined by the distance 106b and the magnitude of the applied voltage. Similarly, as described above, the pads 107a and 107c may be used as measurement pads and an electrical characteristic, such as the conductivity, may be measured along the first direction 105a. For determining the characteristic under consideration along the direction 105b, a second device 100 may be provided adjacent to the device shown in FIG. 1a, wherein the corresponding pads formed along the direction 105a may be provided with a thin insulating layer, while the pads oriented along the direction 105b may be used as measurement sites.

The measurement results obtained by one of the above-identified techniques may be used to define standards or target values for one or more electrical characteristics and may also be advantageously correlated to the electrical performance of actual circuit elements, such as transistor elements formed on corresponding test regions or formed on actual circuit locations. For example, for a specified process sequence during which strain is intentionally generated, a structure as represented by the semiconductor device 100 may be used to control the process flow to achieve a desired final electrical performance of product devices. For instance, process steps related to the global or local creation of strain may be assessed by means of a test structure such as the semiconductor device 100 at different positions on one or more substrates to establish a target value for one or more process parameters of these process steps, wherein the corresponding process steps may then be controlled on the basis of the established target value for one or more substrates to be subsequently processed.

In some embodiments, the semiconductor device 100 may be completed at a moderately early manufacturing stage, for instance when the test pads 104a, 104b, 104c, 104d also serve as contact pads that may directly be contacted by corresponding electrical probes. In this case, strain-related electrical characteristics or other electrical characteristics may thus be assessed prior to the completion of circuit elements such as transistors to provide the potential for controlling the further manufacturing process on the basis of the measurement results.

FIG. 1c schematically shows the semiconductor structure 100 representing a test structure including at least three test pads 104a, 104b, 104c, which are electrically connected to corresponding contact pads 107a, 107b, 107c. The test pads 104a, 104b, 104c are arranged to define the first and second directions 105a, 105b in the same way as shown in FIG. 1a, wherein, also with respect to the respective distances 106a, 106b, the same criteria apply as previously explained. Moreover, as already discussed with reference to FIG. 1a, a further direction 105c of interest along with a corresponding third distance 106c may be defined by the pads 104b and 104c. Regarding any details of manufacturing the structure 100 of FIG. 1c as well as design details with respect to the distances 106a, 106b, and 106c, and the like, the same criteria apply as previously explained with reference to FIGS. 1a and 1b. The embodiment shown in FIG. 1c provides the possibility of measurement direction-dependent electrical characteristics with a reduced number of test pads, thereby reducing the space required for contact pads, thereby reducing the consumption of chip area which may now be used for product devices or other test structures.

FIG. 1d schematically shows a further illustrative embodiment including the four test pads 104a, 104b, 104c, 104d arranged within the specified semiconductor region 102 to establish four different directions of interest, respective two of which are oriented perpendicularly to each other. Moreover, the respective distances 106c, 106d as well as the distances 106a and 106b are substantially identical so that corresponding measurement results may be directly compared with each other.

It should be appreciated that the embodiments described above are illustrative examples, wherein many modifications may be performed with respect to the positioning, the size, the relative distances, the construction, the shape and the number of the test pads 104a, 104b, 104c, 104d.

FIG. 1e schematically shows a cross-sectional view of a further embodiment of the device 100 wherein, for convenience, only two test pads are shown in cross-section. Hence, the semiconductor device 100 may comprise the test pads 104a and 104b and the corresponding metal plugs 108a and 108b to provide electrical contact to corresponding contact pads (not shown). Moreover, the device 100 of FIG. 1e may also comprise a circuit element 120, which may be represented as a line-like element, such as a polysilicon line and the like, having formed thereon the stress-inducing layer 109. The circuit element 120 may be formed along with actual circuit elements, and hence the semiconductor device 100 may enable the measurement of strain-induced effects on the electrical characteristics in direction-dependent manner under conditions that are quite similar to the situation for an actual circuit element. Regarding the technique for establishing corresponding measurement results, the same criteria apply as previously explained.

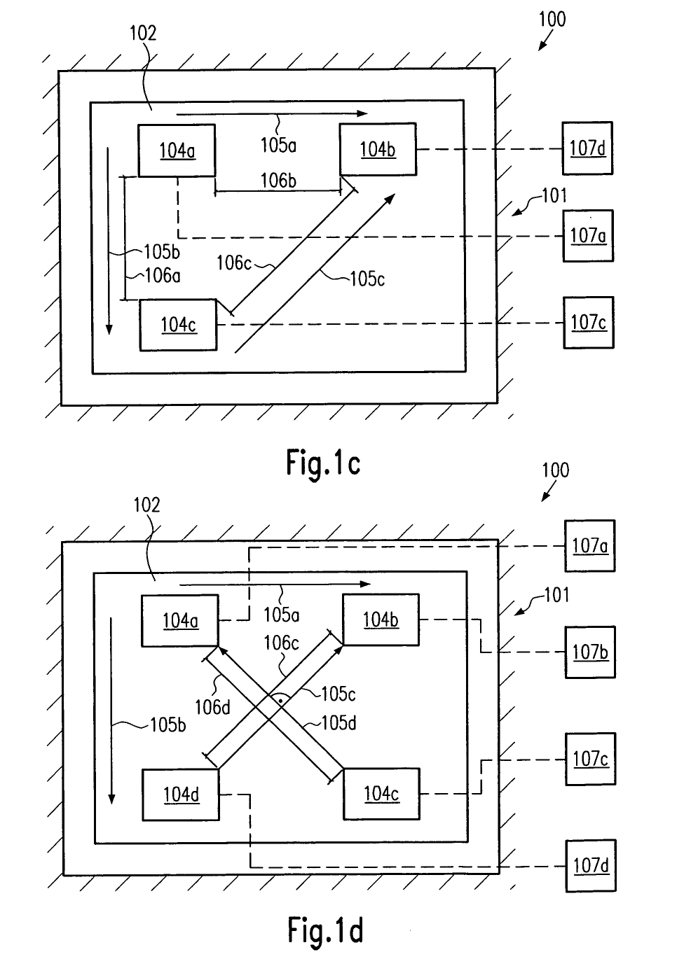

FIG. 2 schematically shows, in plan view, a further illustrative embodiment of the present invention. A test structure 200 comprises a specified semiconductor region 202 having formed therein two differently oriented transistor elements 220 and 230, wherein the transistor 230 defines a first direction of interest 205a and the transistor 220 defines a second direction of interest 205b. Moreover, corresponding first and second distances 206a and 206b may be defined by the respective channel length of the transistors 230 and 220. Furthermore, drain and source regions 221 of the transistor 220 may be connected to corresponding contact pads 207a and 207b, while a gate electrode 222 may be connected to a contact pad (not shown) or may be connected internally to one of the source and drain regions 221. Similarly, drain and source regions 231 of the transistor 230 may be connected to respective contact pads 207c and 207d, while a gate electrode 232 may be connected to a separate contact pad (not shown) or may be internally connected to one of the drain and source regions 231.

The test structure 200 may be formed along with actual circuit elements in correspondence with a specified technology node so that well-established process techniques may be used to form the test structure 200. It should be appreciated that the transistor elements 220 and 230 may be provided with individual trench isolations or may advantageously be formed within the same semiconductor region without any specific isolation structures to isolate the elements 220 and 230. Moreover, the transistor elements 220 and 230 may be provided in close proximity to each other to be in conformity with design rules, yet enabling the assessment of the semiconductor region 202 in both directions 205a and 205b as substantially uniform conditions may prevail at least across that portion of the semiconductor region 202 that is occupied by the transistors 220 and 230.

During operation of the test structure 200, appropriate voltages may be applied to the contact pads 207a, 207b, 207c, 207d to establish a specified current flow, electrical field and the like, as is required for estimating the electrical characteristics, for example, strain induced effects on the charge carrier mobility. Hereby, any effects of manufacturing techniques for actual transistor elements may directly be correlated to the measurement results, thereby enhancing the efficiency of stress and strain related control strategies.

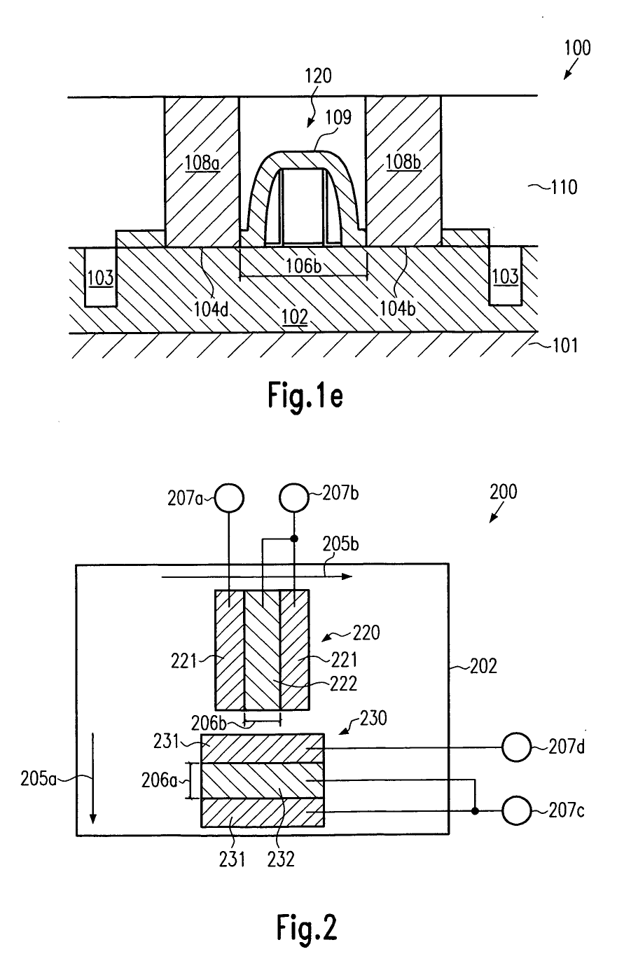

FIG. 3 schematically shows a further illustrative embodiment of a test structure 300 comprising a plurality of test pads 304a, 304b, 304c, 304d arranged in array form to be in contact with a specified semiconductor region 302. The test pads 304a, 304b, 304c, 304d are electrically connected to respective contact pads 307a, 307b, 307c, 307d. Regarding the shape, size, construction, relative position, and the like, the same criteria apply as previously explained with reference to FIGS. 1a-1e and 2. Moreover, the test structure 300 comprises a plurality of internal connections 330a, 330b, 330c, 330d which internally connect respective test pads with each other. In the arrangement shown, the test pads 304a are connected by the connection 330a, for instance provided in the form of a local interconnect, a metal line, and the like. Furthermore, the test pads 304b are connected by the connection 330b, the pads 304c are connected by the connection 330c, and the pads 304d are connected by the connection 330d. It should be appreciated that other arrangements may be readily established by correspondingly designing the connections 330a, 330b, 330c, 330d.

In the present example, a combination of measurement results for a plurality of portions of the region 302 may be obtained for a specified direction of interest by using respective test pads. For example, by determining an electrical conductivity between the pads 304a and 304c, a first direction of interest 305a is defined, wherein measurement results for the respective portions of the region 302 are obtained in this direction, and wherein the influence of the various pairs of pads 304a and 304c on each other is reduced due to the moderately high spacing therebetween. Similarly, other directions of interest, such as a direction 305b, 305c and 305d, may be defined by correspondingly operating the test pads 304a, 304b, 304c, 304d. As is shown, during operation of the test structure 300, measurement results of increased statistical relevance may be obtained, since a higher number of test pads are included in the measurement. Moreover, in some cases it may be considered advantageous to cover a larger area of the semiconductor region 302 to obtain a more meaningful measurement result, while the amount of floor space occupied by the contact pads is kept at a low level.

In the embodiment shown, the number of actually used contact pads is 4, while 8 test pads may be operated to be included in the measurement. It should be appreciated, however, that other electrical configurations may be established in accordance with design and measurement requirements, and in particular each of the test pads in the test structure 300 may be connected to an individual contact pad. For example, two or more of the basic test structures, as described with reference to FIGS. 1a-1e and 2, may be combined to an array.

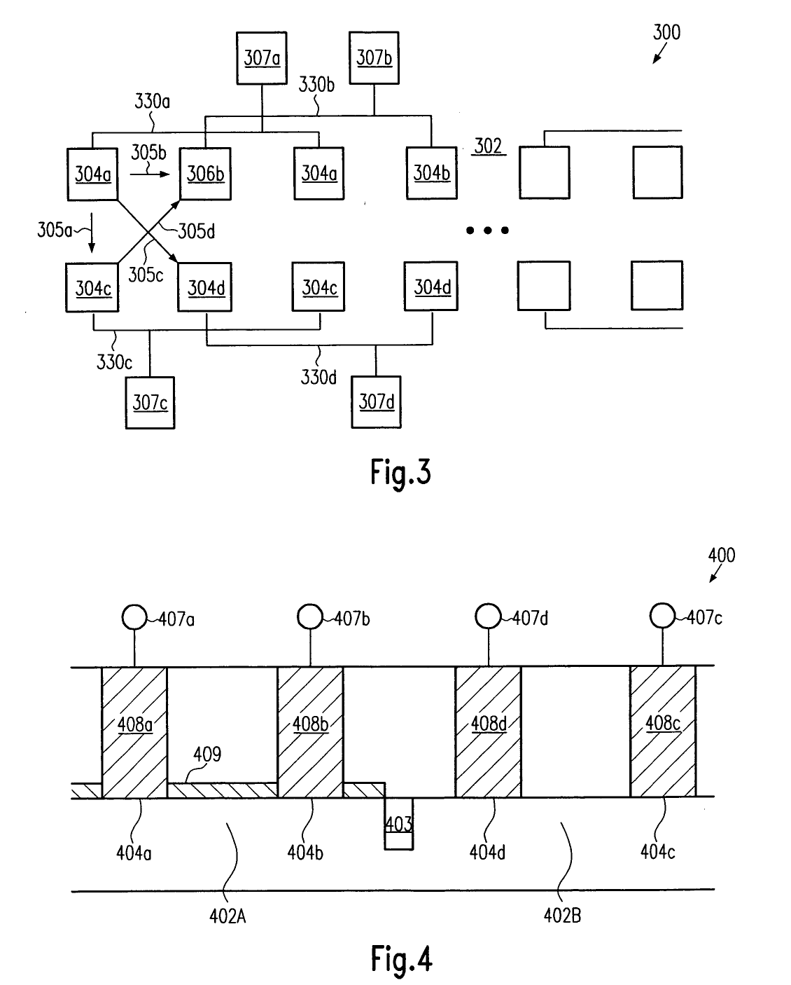

FIG. 4 schematically shows a cross-sectional view of a further illustrative embodiment comprising a test structure 400 including a first semiconductor region 402a and a second semiconductor region 402b. As previously explained, the test structures shown and described above are highly efficient in determining any directional characteristic, i.e., anisotropy, of a specified electrical characteristic, such as the charge carrier mobility, since the measurement results of corresponding pairs of test pads may be expressed as ratio and directly indicate the relative amount of the anisotropy of the characteristic examined. In some cases, the electrical characteristic to be measured may exhibit a substantially isotropic behavior in the semiconductor region under consideration and hence a calibration of the measurement results may be desired to provide meaningful results of the isotropic behavior based on a defined reference measurement reading. For this purpose, a semiconductor region 402b may represent a reference region on which is formed a corresponding test structure that may include at least two test pads 404c and 404d, which may be connected via corresponding metal plugs 408c and 408d with the respective contact pads 407c and 407d. Hereby, the test pads 404c and 404d may be oriented arbitrarily and, although any number of test pads may be provided, two test pads may be enough to produce a reference measurement value. On the other hand, the semiconductor region 402a may have formed thereon a direction-sensitive test structure configuration including a plurality of test pads wherein merely two pads 404a and 404b are shown, and wherein other test pads may be arranged as is, for example, shown and described with reference to the preceding figures. Thus, corresponding metal plugs 408a and 408b may electrically connect the pads 404a and 404b with respective contact pads 407a and 407b. Moreover, the semiconductor regions 402a and 402b may be spaced apart by a sufficient distance to minimize any mechanical coupling between these two regions, or, as shown in FIG. 4, a strain-inducing region 409 may be formed in or on the region 402a to locally induce strain therein, while the reference region 402b lacks the strain-inducing mechanism provided by the region 409. It should be appreciated, however, that the reference region 402b may nevertheless include any strain or stress that may be induced by any other manufacturing processes, components external to the region 402, and the like. Nevertheless, the region 402b may be considered as a reference region with respect to at least one parameter, such as the formation of the stress-inducing region 409 so that the reference data obtained from the region 402b may be considered as reference for at least this parameter.

Regarding the manufacturing of the test structure 400, well-established process techniques may be used in conformity with design requirements for actual circuit elements that may be formed along with the test structure 400.

During the operation of the device 400, measurement results may be gathered for the region 402a and the region 402b, wherein the results of the region 402b may be used as the reference for estimating the non-directional characteristics, e.g., substantially isotropic effect, of the stress-inducing region 409 on a specified electrical characteristic, such as the charge carrier mobility. Regarding the details of the measurement process, the same criteria apply as previously explained with reference to FIGS. 1a-3. It should be appreciated that the test structures for the regions 402a and 402b may also be identical in configuration and may differ in at least one characteristic of the regions 402a and 402b, such as position on the substrate, difference in the manufacturing sequence, and the like.

In other embodiments, a reference value may be established on the basis of a plurality of measurement results obtained from a plurality of different substrates and/or from different positions within a substrate in the form of an average or weighted average value. Hence, the electrical characteristic of interest, even if it is substantially isotropic across a single semiconductor region sampled by a single test structure, may then be estimated with respect to the average value.

As a result, the present invention provides a simple and highly effective test structure and method for operating the same to determine direction-dependent electrical characteristics of a semiconductor region of interest in a highly efficient manner, wherein, even in case of a substantially isotropic behavior, meaningful measurement results may be achieved. Moreover, the present invention enables the investigation of the influence of current or electrical fields on stress or strain dependent electrical characteristics without undue efforts or process flow modifications. Moreover, clear measurement signals may be obtained with commonly used measurement equipment for evaluating the electrical performance of circuit elements, thereby obtaining clear measurement signals that may readily be assessed and that represent a physical correlation between macroscopic and microscopic parameters.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a semiconductor region formed in a device layer located above a substrate; and
a plurality of test pads electrically coupled to said semiconductor region for measuring at least one directional characteristic of said semiconductor region, a first two of said test pads being arranged along a first direction and a second two of said test pads being arranged along a second direction that is different from said first direction.

2. The device of claim 1, wherein a distance between said first two test pads and a distance between said second two test pads is substantially the same.

3. The device of claim 1, wherein a distance between said first two test pads and a distance between said second two test pads is different.

4. The device of claim 1, further comprising a plurality of contact pads, each contact pad being electrically connected to at least one of said plurality of test pads.

5. The device of claim 1, wherein said semiconductor region is a strained region.

6. The device of claim 1, wherein said semiconductor region is a stressed region.

7. The device of claim 1, further comprising at least three test pads.

8. The device of claim 1, further comprising at least four test pads.

9. The device of claim 1, wherein said first and second directions are substantially perpendicular.

10. The device of claim 1, further comprising a reference semiconductor region formed in said device layer, the reference semiconductor region differing from said semiconductor region in at least one of strain and stress, the reference semiconductor region comprising a pair of reference test pads in contact with said reference semiconductor region and arranged to define a predefined distance therebetween.

11. The device of claim 1, wherein at least two of said test pads represent drain and source regions of a first transistor structure.

12. The device of claim 11, wherein a gate electrode of said first transistor structure is internally connected with one of said drain and source regions.

13. The device of claim 11, wherein at least two further test pads represent drain and source regions of a second transistor structure, wherein a transistor length direction of said first transistor structure is oriented along said first direction and a transistor length direction of said second transistor structure is oriented along said second direction.

14. A semiconductor device, comprising:
a semiconductor region located in a device layer of said semiconductor device and formed above a substrate; and
a test structure formed in said semiconductor region and configured to determine an electrical characteristic of said semiconductor region in at least two different directions.

15. The device of claim 14, wherein said semiconductor region comprises an internal strain.

16. The device of claim 14, wherein said test structure comprises a plurality of test pads electrically coupled to said semiconductor region for measuring at least one directional characteristic of said semiconductor region, a first two of said test pads being arranged along a first direction and a second two of said test pads being arranged along a second direction that is different from said first direction.

17. The device of claim 14, further comprising a plurality of contact pads, each contact pad being electrically connected to at least one of said plurality of test pads.

18. The device of claim 14, wherein said first and second directions are substantially perpendicular.

19. The device of claim 16, wherein a distance between said first two test pads and a distance between said second two test pads is substantially the same.

20. The device of claim 14, further comprising a second semiconductor region that differs in at least one characteristic from said semiconductor region, the second semiconductor region including a second test structure configured to determine a conductivity of said second semiconductor region along at least one direction.

21. The device of claim 14, wherein said test structure comprises three test pads.

22. The device of claim 14, wherein said test structure comprises at least four test pads.

23. A method, comprising:
determining, with respect to at least two linearly independent directions, an electrical property of a semiconductor region located in a device layer of a semiconductor device; and
evaluating at least one specific characteristic influencing a charge carrier mobility in said semiconductor region on the basis of said determined electrical property.

24. The method of claim 23, wherein determining said electrical property comprises determining an electrical resistance of said semiconductor region between two contact portions formed on said semiconductor region along one of said two linearly independent directions.

25. The method of claim 24, wherein determining said electrical property comprises determining an electrical resistance of said semiconductor region between two contact portions formed on said semiconductor region along the other one of said two linearly independent directions.

26. The method of claim 23, wherein said at least one characteristic comprises an internal strain of said semiconductor region.

27. The method of claim 23, further comprising defining said semiconductor region within said device layer to comply with predefined dimensions.

28. The method of claim 27, wherein said predefined dimensions are selected to substantially correspond to specified design dimensions of a circuit element formed in said device layer.

29. The method of claim 23, further comprising forming a plurality of circuit elements in said device layer by a process flow including at least one adjustable process parameter for introducing strain in at least some of the circuit elements.

30. The method of claim 29, further comprising controlling said at least one adjustable process parameter on the basis of said at least one characteristic during the fabrication of one or more further semiconductor devices including said plurality of circuit elements, wherein said one or more semiconductor devices are formed on one or more different substrates.

31. The method of claim 23, wherein determining said electrical property comprises determining an electrical resistance of said semiconductor region between two contact portions formed on said semiconductor region along one of said two linearly independent directions while applying a voltage across two contact portions formed on said semiconductor region along the other one of said two linearly independent directions.

32. The method of claim 23, further comprising determining a reference value of said electrical property when a first value of said electrical property for one of the at least two linearly independent directions is substantially the same as a second value of said electrical property along the other one of said at least two linearly independent directions.

33. The method of claim 32, wherein said reference value is determined in a second semiconductor region formed in combination with said semiconductor region in a process that locally differs between said semiconductor region and said second semiconductor region in at least one process parameter.

34. The method of claim 33, wherein said at least one process parameter is a parameter affecting an internal strain in said semiconductor region and said second semiconductor region.
